(19) United States
(12) Patent Application Publication
(10) Pub. No.: US 2016/0233159 A1
(43) Pub. Date: Aug. 11, 2016

(54) INTEGRATED CIRCUIT DEVICE INCLUDING MULTIPLE VIA CONNECTORS AND A METAL STRUCTURE HAVING A LADDER SHAPE

(71) Applicant: QUALCOMM Incorporated, San Diego, CA (US)

(72) Inventors: Stanley Seungchul Song, San Diego, CA (US); Niladri Narayan Mojumder, San Diego, CA (US); Da Yang, San Diego, CA (US); Choh Fei Yeap, San Diego, CA (US)

(21) Appl. No.: 14/855,939

(22) Filed: Sep. 16, 2015

Related U.S. Application Data
(60) Provisional application No. 62/114,563, filed on Feb. 10, 2015.

(51) Int. Cl. H01L 23/522; H01L 21/768; H01L 27/11

(52) U.S. Cl. CPC H01L 23/5226; H01L 27/1104; H01L 21/76802; H01L 21/76877

(57) ABSTRACT

In a particular aspect, an apparatus includes a first via of an integrated circuit. The apparatus includes a second via of the integrated circuit. The apparatus includes a first via connector coupled to the first via. The apparatus includes a second via connector coupled to the second via. The apparatus further includes a metal structure separated from and encircling the first via connector and the second via connector.

### I. CROSS-REFERENCE TO RELATED APPLICATIONS

The present application claims priority from U.S. Provisional Patent Application No. 62/114,563, filed Feb. 10, 2015 and entitled “INTEGRATED CIRCUIT DEVICE INCLUDING MULTIPLE VIA CONNECTORS AND A METAL STRUCTURE HAVING A LADDER SHAPE,” the content of which is expressly incorporated herein by reference in its entirety.

### II. FIELD

The present disclosure is generally related to an integrated circuit device including multiple via connectors and a metal structure having a ladder shape.

### III. DESCRIPTION OF RELATED ART

Advances in technology have resulted in smaller and more powerful computing devices. For example, a variety of portable personal computing devices, including wireless telephones such as mobile and smart phones, tablets and laptop computers are small, lightweight, and easily carried by users. These devices can communicate voice and data packets over wireless networks. Further, many such devices incorporate additional functionality such as a digital still camera, a digital video camera, a digital recorder, and an audio file player. Also, such devices can process executable instructions, including software applications, such as a web browser application, that can be used to access the Internet. As such, these devices can include significant computing and networking capabilities.

In some implementations of a memory (e.g., a static random access memory (SRAM)) that use a 1-dimensional (1D) metal design to form a first metal layer (i.e., a “metal-1” or M1 layer), different metal “tracks” are used for a word line of a memory cell and for a power line of the memory cell. In some implementations, a word line may be formed in a second metal layer (i.e., a “metal-2” or M2 layer), and a word line connecting pad may be formed in the first metal layer. To form word line connecting pads, a cut process may be performed using a cut metal pattern. As integrated circuit design sizes decrease (i.e., scale) with fabrication technology, dimensions of the cut metal pattern, such as a width of the cut metal pattern or a pitch between the cut metal pattern and a proximate metal line, also decrease. As the dimensions of the cut metal pattern continue to decrease, patterning the cut metal pattern becomes more difficult.

### IV. SUMMARY

The present disclosure describes an integrated circuit that includes multiple via connectors and a metal structure that is separate from and that encircles (e.g., surrounds) the multiple metal connectors. For example, the metal structure may have a ladder shape and may encircle the multiple via connectors. The via connectors and the metal structure may be included in a first metal layer (e.g., a “metal-1” or M1 layer) of an integrated circuit. Each via connector may be coupled to a group of vias that are configured to couple a circuit component included in a first layer (e.g., a circuit component layer beneath the first metal layer) and a word line included in a second metal layer (e.g., a “metal-2” or M2 layer). In a particular implementation, a via connector (and a corresponding group of vias) may be configured to couple a gate of a transistor included in the first layer to the word line included in the second metal layer. Because the metal structure is separate from the multiple via connectors, each via connector is isolated from other via connectors and thereby enables each group of vias to couple together different elements from the first layer and the second metal layer. Additionally, the metal structure having the ladder shape may be formed using one or more mandrels and multiple spacers during a fabrication process. Because the metal structure encircles the multiple via connectors, the via connectors are formed without performing a cut process using a cut metal pattern.

In a particular aspect, an apparatus includes a first via and a second via. The apparatus includes a first via connector coupled to the first via and a second via connector coupled to the second via. The apparatus further includes a metal structure separated from and encircling the first via connector and the second via connector.

In another particular aspect, a method of fabricating an integrated circuit device includes forming a first layer that includes one or more circuit elements. The method further includes forming a second layer that includes a first via connector, a second via connector, and a metal structure, the metal structure separated from and encircling the via connectors.

In a particular aspect, an apparatus includes means for coupling a first group of vias. The apparatus includes means for coupling a second group of vias. The apparatus further includes means for conducting. The means for conducting may be separate from and may encircle the means for coupling the first group of vias and the means for coupling the second group of vias.

In another particular aspect, a non-transitory computer-readable medium stores instructions that, when executed by a processor, cause the processor to perform operations including initiating formation of a first layer that includes a first circuit element and a second circuit element. The operations include initiating formation of multiple mandrel structures. The operations include initiating deposition of spacing material proximate to each of the multiple mandrel structures to form spacers. The operations include initiating removal of the multiple mandrel structures. The operations include initiating performance of a hard mask etch process to form trenches around the spacers. The operations include initiating removal of the spacers. The operations include initiating filling of the trenches with metal to produce a first via connector, a second via connector, and a metal structure. The metal structure may be separate from and may encircle the first via connector and the second via connector. The operations further include initiating patterning of a first via coupled to the first circuit element and the first via connector and patterning of a second via coupled to the second circuit element and the second via connector.

One particular advantage provided by at least one of the disclosed aspects is an integrated circuit that includes multiple via connectors and a metal structure that is separate from and encircles the multiple via connectors. By forming such a metal structure, multiple via connectors may be formed without use of a cut metal pattern, thereby reducing complexity and/or cost of a fabrication process. Additionally, the metal structure may have a ladder shape, which may enable use of fewer vias than other implementations, and may reduce VSS fluctuations on the metal structure.

Other aspects, advantages, and features of the present disclosure will become apparent after review of the entire application, including the following sections: Brief Description of the Drawings, Detailed Description, and the claims.

### V. BRIEF DESCRIPTION OF THE DRAWINGS

FIG. 1 is a diagram of a side view of an integrated circuit device including multiple via connectors and a metal structure that is separate from and encircles the multiple via connectors;

FIG. 2 is a diagram of a top-down view of the integrated circuit device of FIG. 1;

FIGS. 3A-D illustrate stages of a first process to fabricate the integrated circuit device of FIG. 1;

FIGS. 4A-D illustrate stages of a second process to fabricate the integrated circuit device of FIG. 1;

FIG. 5 is a flow chart that illustrates a method of fabricating the integrated circuit device of FIG. 1;

FIG. 6 is a block diagram of a device including the integrated circuit device of FIG. 1; and

FIG. 7 is a data flow diagram of an illustrative aspect of a manufacturing process to fabricate a device including the integrated circuit device of FIG. 1.

### VI. DETAILED DESCRIPTION

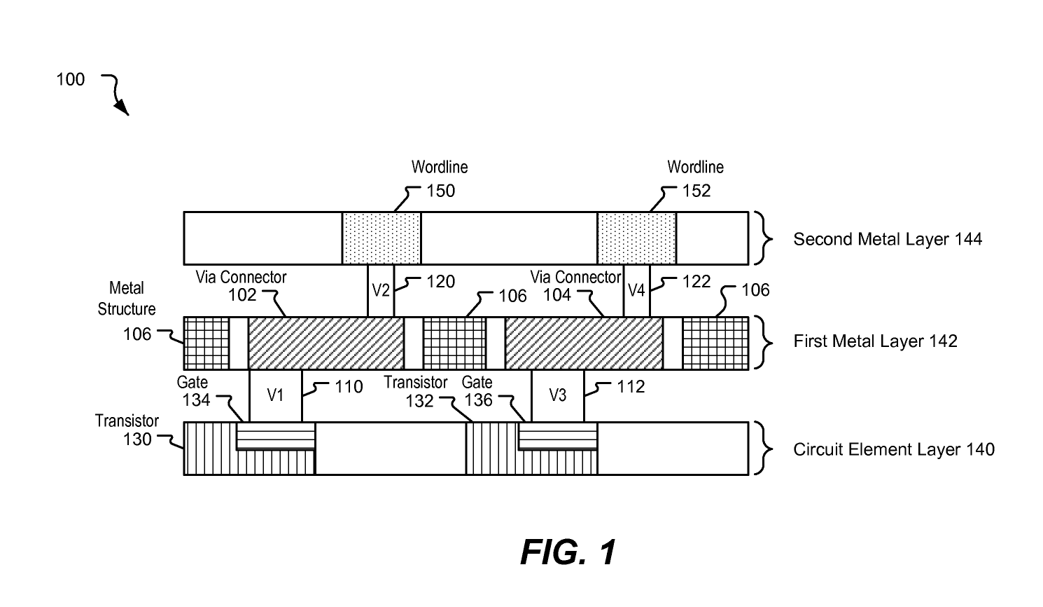

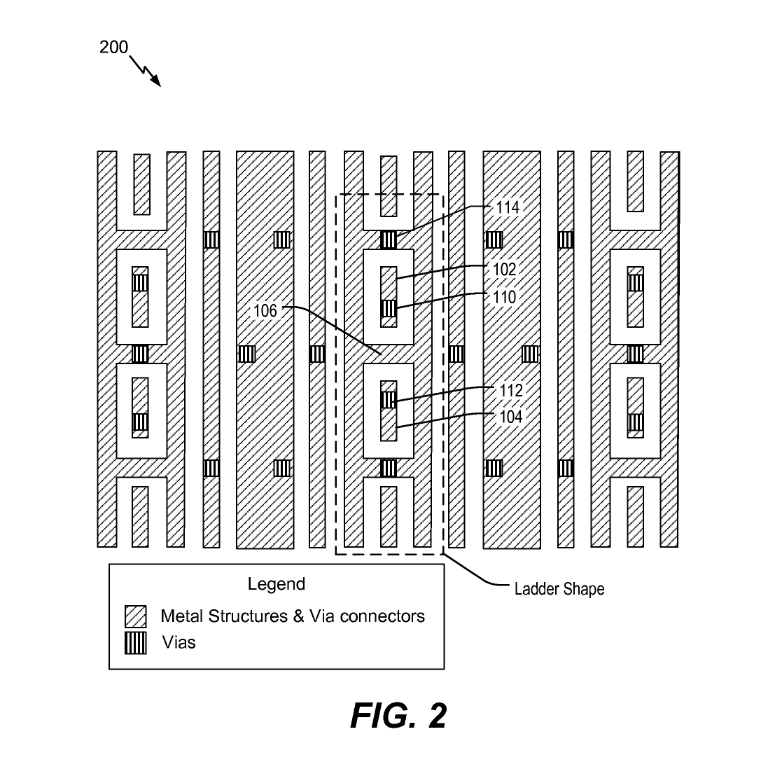

Referring to FIG. 1, a diagram of a side view of an integrated circuit device 100 that includes multiple via connectors and a metal structure is shown. The integrated circuit device 100 includes a first via connector 102, a second via connector 104, and a metal structure 106. The metal structure 106 is separate from and encircles (e.g., surrounds) the first via connector 102 and the second via connector 102. The metal structure 106 may be separated from the first via connector 102 and the second via connector 104 by a dielectric (e.g., the non-shaded regions between the metal structure 106, the first via connector 102, and the second via connector 104 in FIG. 1). The metal structure 106 may encircle the first via connector 102 and the second via connector 104. For example, as illustrated in FIG. 2, a portion of the metal structure 106 may encircle a first region, and the first via connector 102 may be located in the first region. Additionally, another portion of the metal structure 106 may encircle a second region, and the second via connector 104 may be located in the second region. As further described with reference to FIG. 2, the first metal structure may have a ladder shape.

As illustrated in FIG. 1, the first via connector 102, the second via connector 104, and the metal structure 106 may be included in a first metal layer 142 (e.g., a “metal-1” or M1 layer), which may be disposed above a circuit element layer 140 and below a second metal layer 144 (e.g., a “metal-2” or M2 layer) in the orientation illustrated in FIG. 1. The orientation illustrated in FIG. 1 is illustrative, and the integrated circuit device 100 may have other orientations in other implementations. In a particular aspect, the first via connector 102, the second via connector 104, and the metal structure 106 are included in the first metal layer 142 of the integrated circuit device 100. In this aspect, the first metal layer 142 is disposed above the circuit element layer 140 that contains at least one circuit element.

The first via connector 102 may be coupled to a first group of vias that includes a first via 110 (V1) and second via 120 (V2), and the second via connector 104 may be coupled to a second group of vias that includes a third via 112 (V3) and a fourth via 122 (V4). The first via 110 and the third via 112 may be included in the same via layer, and the second via 120 and the fourth via 122 may be included in the same via layer, as illustrated in FIG. 1. The first via 110 may be coupled to a first circuit element, such as a first gate 134 of a first transistor 130. The first transistor 130 may be included in the circuit element layer 140. The second via 120 may be coupled to a first word line 150 included in the second metal layer 144. Similarly, the third via 112 may be coupled to a second circuit element, such as a second gate 136 of a second transistor 132. The second transistor 132 may be included in the circuit element layer 140. The fourth via 122 may be coupled to a second word line 152 included in the second metal layer 144.

Because the metal structure 106 is separate from each of the via connectors 102 and 104, each of the via connectors (e.g., 102 and 104) is isolated and may be coupled to different devices or structures in the circuit element layer 140 and the second metal layer 144. For example, the first via connector 102 may be electrically isolated from (e.g., not electrically coupled to) the second via connector 104. The first via connector 102 may be coupled to a different elements in the circuit element layer 140 and the second metal layer 144 than the second via connector 104.

In some implementations, metal lines in the first metal layer 142 may be aligned in a first alignment direction (e.g., horizontally), and metal lines in the second metal layer 144 may be aligned in a second alignment direction (e.g., vertically). For example, the via connectors 102 and 104 may be routed in a first alignment direction, and the word lines 150 and 152 may be routed in a second alignment direction, as illustrated in FIG. 1. This alignment may enable the first via connector 102 to be coupled to the first word line 150 and enable the second via connector 104 to be coupled to the second word line 152.

In some implementations, the integrated circuit device 100 may include or correspond to a memory device (e.g., a memory including one or more memory cells). For example, the integrated circuit device 100 may include or correspond to a static random access memory (SRAM) device. The word lines 150 and 152 may be coupled to SRAM cells of the SRAM device, and the transistors 130 and 132 may correspond to transistors, such as pass-gate transistors, of an SRAM cell. In a particular implementation, the SRAM cell may be a six transistor (6T) SRAM cell.

In some implementations, the first via connector 102 and the second via connector 104 may include (or be referred to as) “word line connection pads.” The first via connector 102 may include or correspond to a word line connection pad coupled to the first word line 150 of a memory cell. Additionally, the second via connector 104 may include or correspond to a word line connection pad coupled to the second word line 152 of a memory cell.

In some implementations, the metal structure 106 includes a voltage source connection. For example, the metal structure 106 may be a metal line that is coupled to a voltage source of a memory. In some implementations, the metal structure 106 may be coupled to a voltage source (VSS). In other implementations, the metal structure 106 may be coupled to ground. One or more transistors of the memory may be coupled to VSS (or ground) by being coupled to the metal structure 106. In a particular implementation, the metal structure 106 may be a voltage source connection for two adjacent memory cells. In this implementation, the metal structure 106 may be referred to as a “merged VSS line.”

In a particular aspect, the first via connector 102 may couple the first via 110 to the second via 120, and the first via 110 and the second via 120 may form a first via group. The second via connector 104 may couple the third via 112 to the fourth via 122, and the third via 112 and the fourth via 122 may for a second via group. Additionally, the first via 110 may couple the first gate 134 of the first transistor 130 to the first via connector 102, and the second via 120 may couple the first via connector 102 to the first word line 150. In some implementations, the first gate 134 is included in a first layer (e.g., the circuit element layer 140) of the integrated circuit device 100. The first via connector 102, the second via connector 104, and the metal structure 106 are included in the first metal layer 142 of the integrated circuit device 100. The first word line 150 is included in the second metal layer 144 of the integrated circuit device 100. In some implementations, the integrated circuit device 100 includes or corresponds to a SRAM device. The first transistor 130 and the first word line 150 may be included in a 6T memory cell of the SRAM device.

By forming the via connectors 102 and 104 and the metal structure 106, as further described herein, the via connectors 102 and 104 may be formed without performing a cut process using a cut metal pattern. Because the metal structure 106 is separate from and encircles the via connectors 102 and 104, each of the via connectors 102 and 104 are able to be coupled to different structures in other layers of the integrated circuit device 100. Coupling the via connectors 102 and 104 to different structures may reduce complexity of routing in the integrated circuit device 100. Additionally, because the metal structure 106 is formed separate from and encircling the via connectors 102 and 104, the metal structure 106 may be formed without using a cut metal pattern, as further described herein. Forming the metal structure 106 without using a cut metal pattern reduces complexity and/or cost of a fabrication process of the integrated circuit device 100. Additionally, the metal structure 106 may have reduced VSS fluctuations due to the ladder shape as compared to VSS lines in other memories that do not have a ladder shape.

Referring to FIG. 2, a diagram of a top-down view of the integrated circuit device 100 of FIG. 1 is shown and designated 200. The first via connector 102, the second via connector 104, the metal structure 106, the first via 110, the third via 112, and a fifth via 114 are labeled. Vias to the second metal layer 144 are not illustrated for ease of illustration.

As illustrated in FIG. 2, the metal structure 106 has a ladder shape. The metal structure 106 having the ladder shape may enable the metal structure 106 to be separate from and to encircle each of the first via connector 102 and the second via connector 104. To illustrate, a first portion of the metal structure 106 encircles the first via connector 102, and a second portion of the metal structure 106 encircles the second via connector 104. Additionally, the metal structure 106 is separate from the via connectors 102 and 104. In some implementations, the metal structure 106 is separated from the via connectors 102 and 104 by a dielectric material (e.g., the unshaded regions illustrated in FIG. 2). Although one metal structure and two via connectors are described, in other implementations more than one metal structure and more than two via connectors may be formed. For example, as illustrated in FIG. 2, multiple metal structures having ladder shapes may be formed, and each metal structure may be separate from and may encircle multiple via connectors. The multiple metal structures and multiple via connectors may be included in a memory device, such as an SRAM memory array.

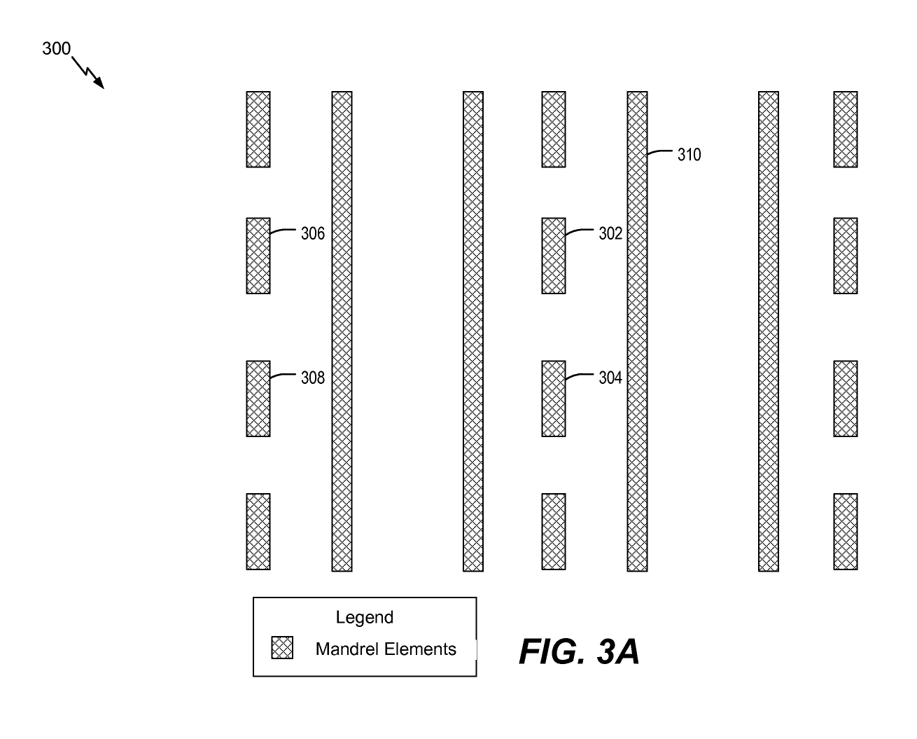

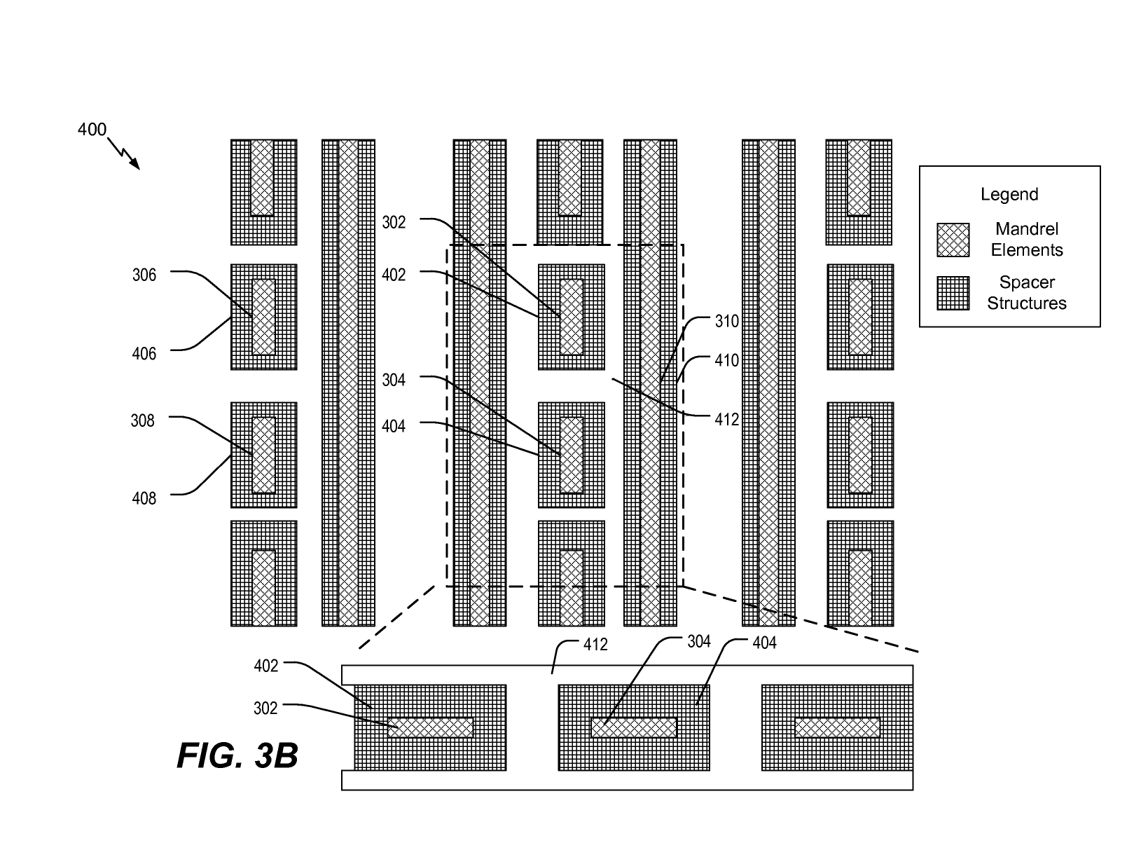

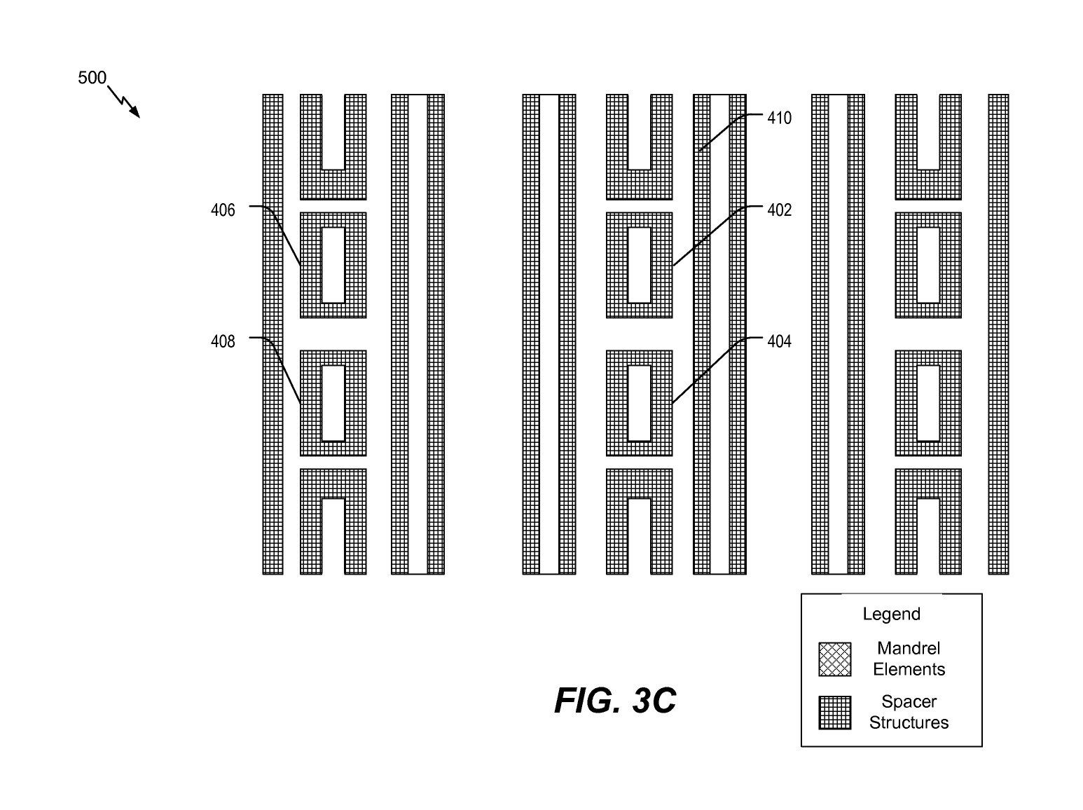

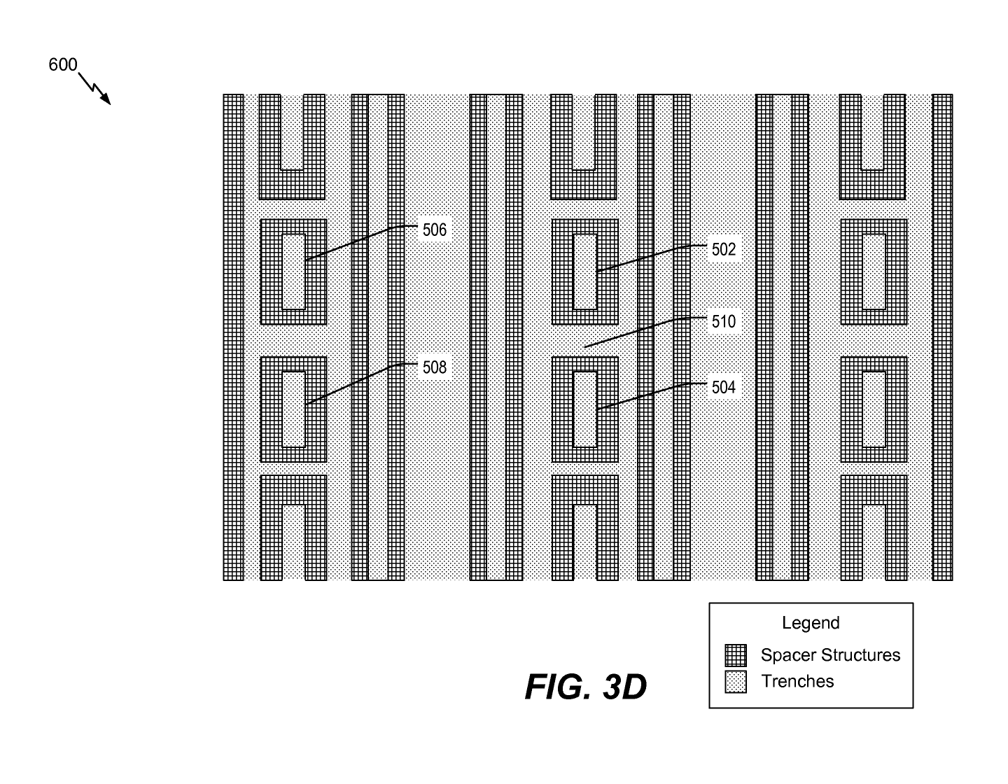

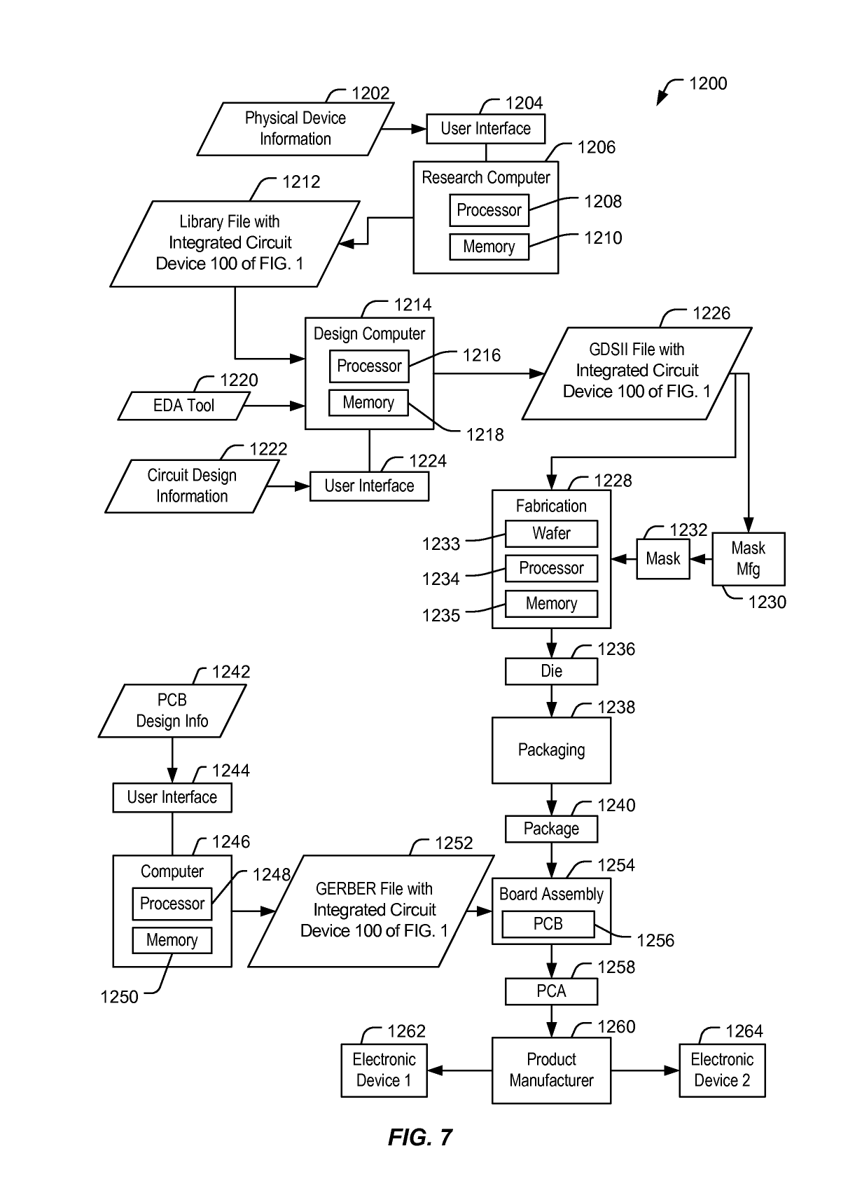

FIGS. 3A-D illustrate stages of a first process to fabricate the integrated circuit device 100 of FIG. 1. In a particular implementation, the steps of the first process may be initiated and/or performed by one or more devices described with reference to FIG. 7.

Referring to FIG. 3A, a first illustrative diagram of at least one stage of a first process of fabricating an integrated circuit device is shown and designated 300. The integrated circuit device may include or correspond to the integrated circuit device 100 of FIG. 1. As illustrated in FIG. 3A, multiple mandrels may be formed on a layer of the integrated circuit device. The multiple mandrels may include a first group of non-contiguous mandrel elements including a first mandrel element 302 and a second mandrel element 304. The multiple mandrels may also include a second group of non-contiguous mandrel elements including a third mandrel element 306 and a fourth mandrel element 308. The multiple mandrels may also include a unitary mandrel 310. The unitary mandrel 310 may be proximate to the first group of non-contiguous mandrel elements. As illustrated in FIG. 3A, each of the first group of non-contiguous mandrel elements, the second group of non-contiguous mandrel elements, and the unitary mandrel 310 may have a first alignment direction (e.g., horizontal or vertical).

Referring to FIG. 3B, a second illustrative diagram of at least one stage of the first process of fabricating the integrated circuit device is depicted and designated 400. As illustrated in FIG. 3B, spacer material may be deposited proximate to the multiple mandrel structures to form multiple spacer structures 402, 404, 406, 408, and 410. As illustrated in FIG. 3B, spacer structures 402 and 404 may correspond to the first group of non-contiguous mandrel elements, spacer structures 406 and 408 may correspond to the second group of non-contiguous mandrel elements, and spacer structure 410 may correspond to the unitary mandrel 310. FIG. 3B also illustrates an expanded view of the first group of non-contiguous mandrel elements and the spacer structures 402 and 404. As illustrated in the expanded view, the mandrel elements 302 and 304 and the spacer structures 402 and 404 are separated by gap-space patterns 412. The gap-space patterns 412 may be used in further stages of the process of fabricating the integrated circuit device to form the metal structure 106.

Referring to FIG. 3C, a third illustrative diagram of at least one stage of the first process of fabricating the integrated circuit device is shown and designated 500. As illustrated in FIG. 3C, after forming the spacer structures 402, 404, 406, 408, and 410, the multiple mandrel structures are removed. Removal of the multiple mandrel structures is performed without performing a cut process using a cut metal pattern.

Referring to FIG. 3D, a fourth illustrative diagram of at least one stage of the first process of fabricating the integrated circuit device is shown and designated 600. As illustrated in FIG. 3D, after removal of the multiple mandrel structures, the spacer structures may be used as a hard mask during performance of a hard mask etching process. Performance of the hard mask etching process forms trenches 502, 504, 506, 508, and 510. For example, trenches 502 and 504 may correspond to a first group of non-contiguous mandrel elements. Trenches 506 and 508 may correspond to a second group of non-contiguous mandrel elements. After forming the trenches 502-510, the spacer structures 402-410 may be removed. The trenches 502 and 504 may be filled with metal to form the via connectors 102 and 104, and the trench 510 may be filled to form the metal structure 106, as shown in FIG. 2. Trenches 506 and 508 may be filled to form additional metal structures.

Because the multiple via connectors 102 and 104 and the metal structure 106 are formed using the multiple mandrel structures, the via connectors 102 and 104 are formed without performing a cut process using a cut metal pattern. To illustrate, in other fabrication processes, small metal structures such as the via connectors 102 and 104 that have a tight pitch to surrounding metal structures (e.g., the metal structure 106) are formed by forming larger metal structures and performing a cut process using a cut mask to remove portions of the larger metal structure, resulting in the small metal structures. Performing a cut process using a cut metal pattern increases complexity and cost of a fabrication process. Thus, the steps illustrated in FIGS. 3A-D reduce complexity and cost of the fabrication process by avoiding performance of a cut process using a cut metal pattern.

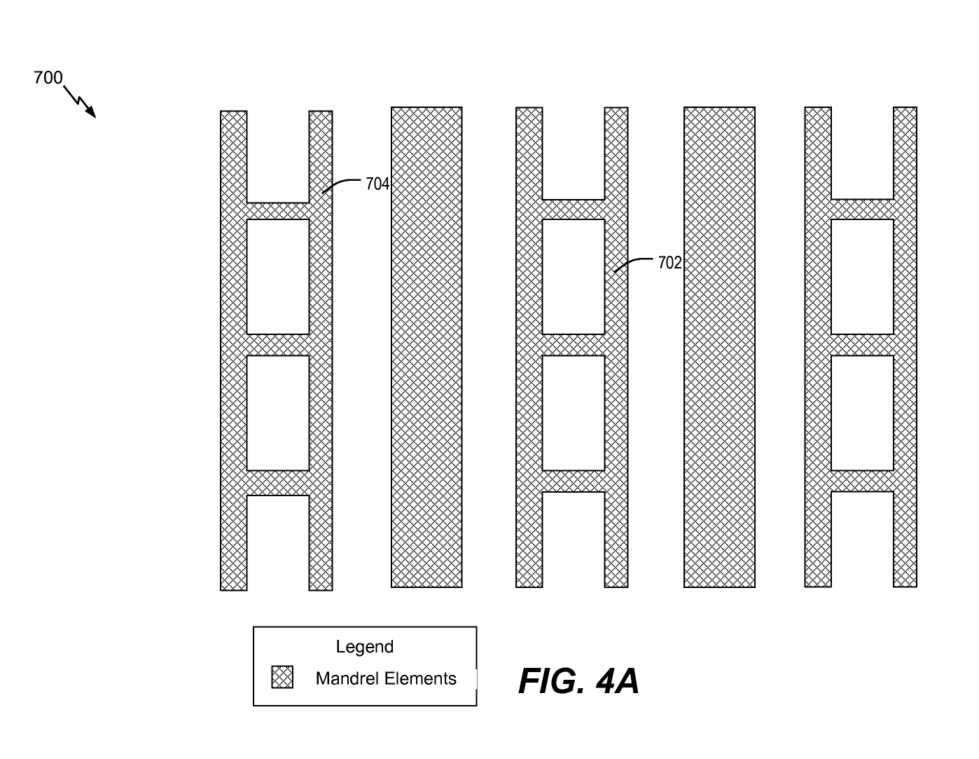

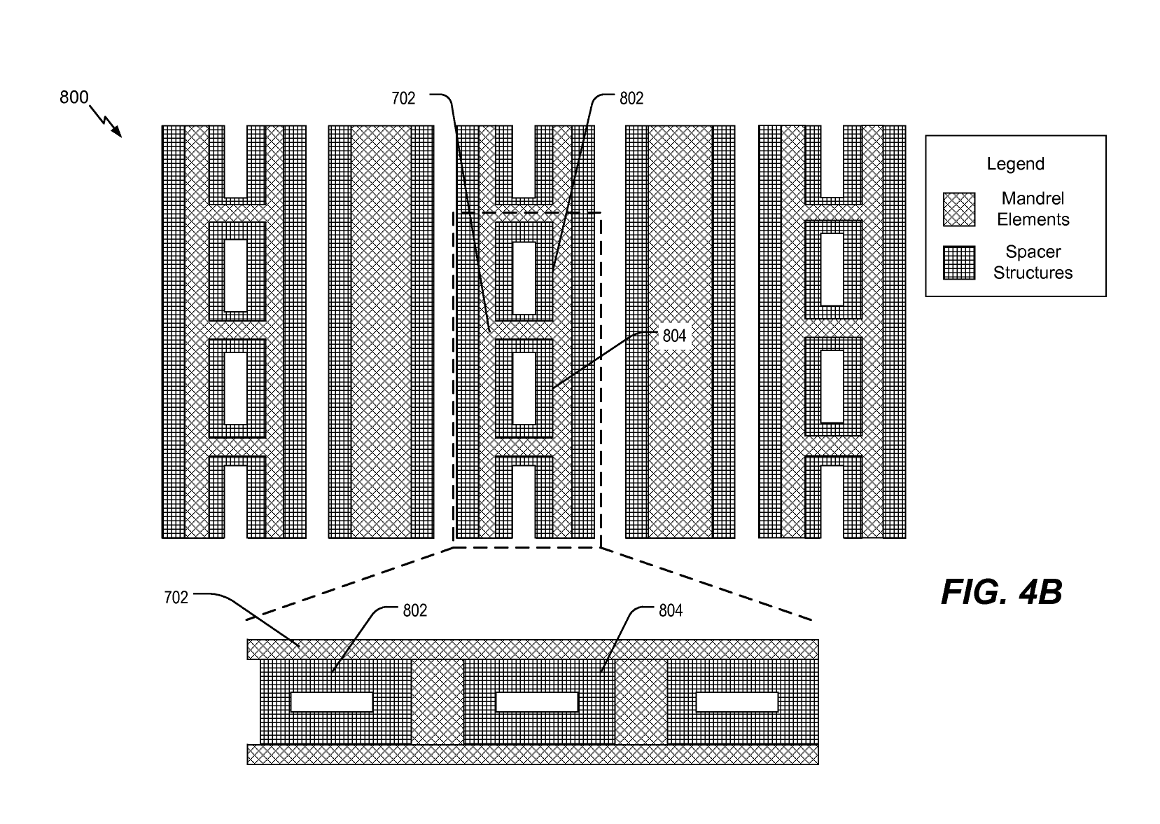

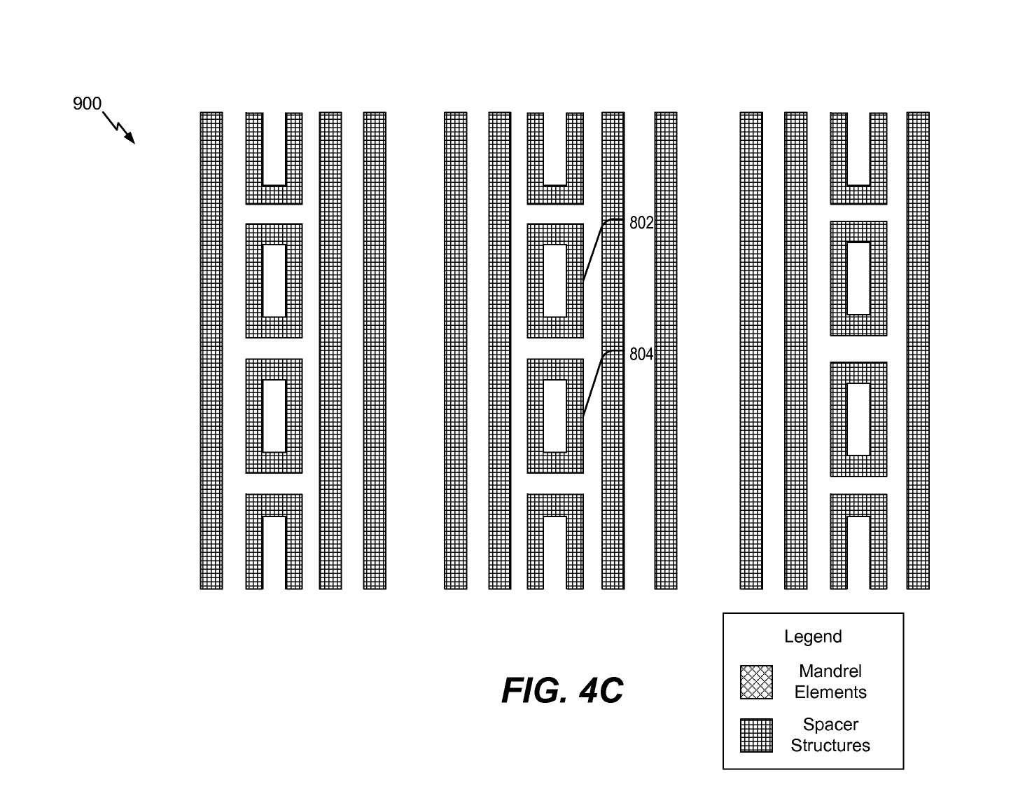

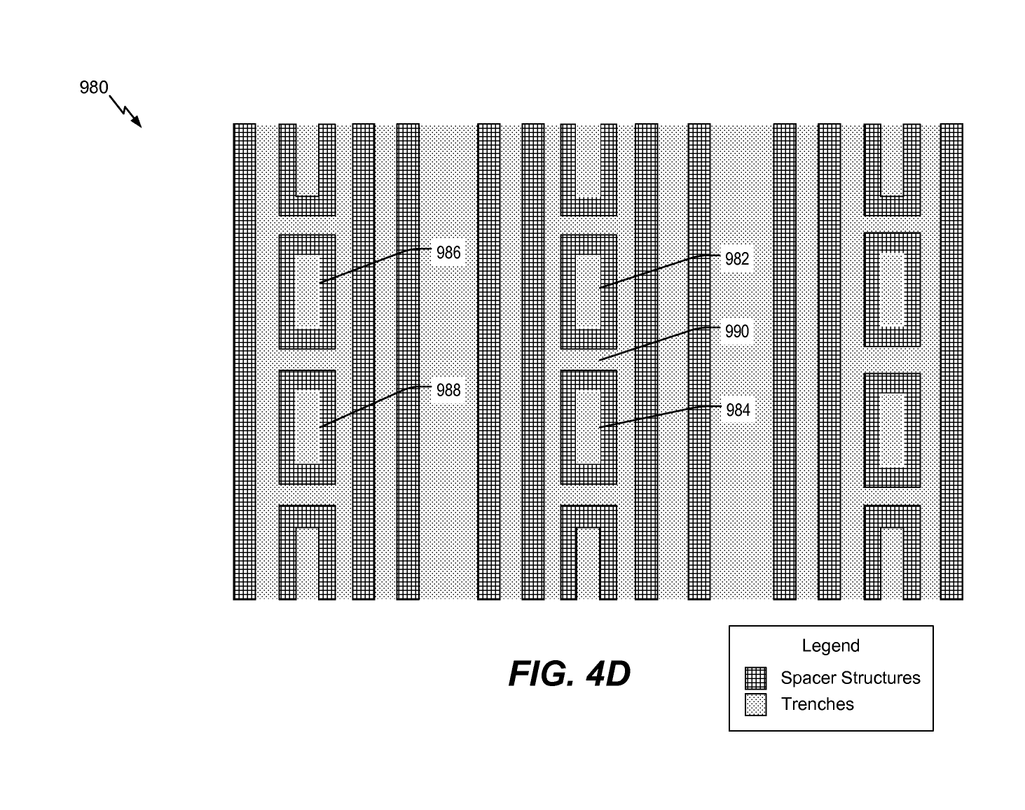

FIGS. 4A-D illustrate stages of a second process to fabricate the integrated circuit device 100 of FIG. 1. In a particular implementation, the steps of the first process may be initiated and/or performed by one or more devices described with reference to FIG. 7.

Referring to FIG. 4A, a second illustrative diagram of at least one stage of a second process of fabricating an integrated circuit device is shown and designated 700. The integrated circuit device may include or correspond to the integrated circuit device 100 of FIG. 1. As illustrated in FIG. 4A, multiple mandrel structures may be formed. The multiple mandrel structures may include a mandrel structure 702 having a ladder shape. The multiple mandrel structures may also include a second mandrel structure 704 having a ladder shape. The mandrel structures may be formed having a ladder shape, instead of in groups of non-contiguous mandrel elements, as shown in FIG. 3A.

Referring to FIG. 4B, a second illustrative diagram of at least one stage of the second process of fabricating an integrated circuit device is shown and designated 800. As illustrated in FIG. 4B, spacer material may be deposited proximate to the multiple mandrel structures 702 to form spacer structures 802 and 804. The spacer structures 802 and 804 may be formed within portions of the mandrel structure 702 having the ladder shape. Additionally, the ladder shape of mandrel structure 702 is shown in an expanded view. In the expanded view of the mandrel structure 702, the mandrel structure 702 is illustrated with spacer structures and gap space patterns between connections of the mandrel structure 702.

Referring to FIG. 4C, a third illustrative diagram of at least one stage of the second process of fabricating the integrated circuit device is shown and designated 900. As illustrated in FIG. 4C, the multiple mandrel structures may be removed, leaving the spacer structures 802 and 804. The multiple mandrel structures may be removed without performing a cut process using a cut mask pattern.

Referring to FIG. 4D, a fourth illustrative diagram of at least one stage of the second process of fabricating the integrated circuit device is shown and designated 980. As illustrated in FIG. 4D, after removal of the multiple mandrel structures, the spacer structures may be used as a hard mask during performance of a hard mask etching process. Performance of the hard mask etching process forms trenches 982, 984, 986, 988, and 990. Trenches 982 and 984 may correspond to a first group of non-contiguous mandrel elements. Trenches 986 and 988 may correspond to a second group of non-contiguous mandrel elements. After forming the trenches 982-990, the spacer structures 802 and 804 may be removed. The trenches 982 and 984 may be filled with metal to form the via connectors 102 and 104, and the trench 990 may be filled to form the metal structure 106, as shown in FIG. 2. Trenches 986 and 988 may be filled to form additional metal structures.

Because the multiple via connectors 102 and 104 and the metal structure 106 are formed using the multiple mandrel structures, the via connectors 102 and 104 and the metal structure 106 are formed without performing a cut process using a cut metal pattern. Performing a cut process using a cut metal pattern increases complexity and cost of a fabrication process. Thus, the steps illustrated in FIGS. 4A-C reduce complexity and cost of the fabrication process by avoiding performance of a cut process using a cut metal pattern.

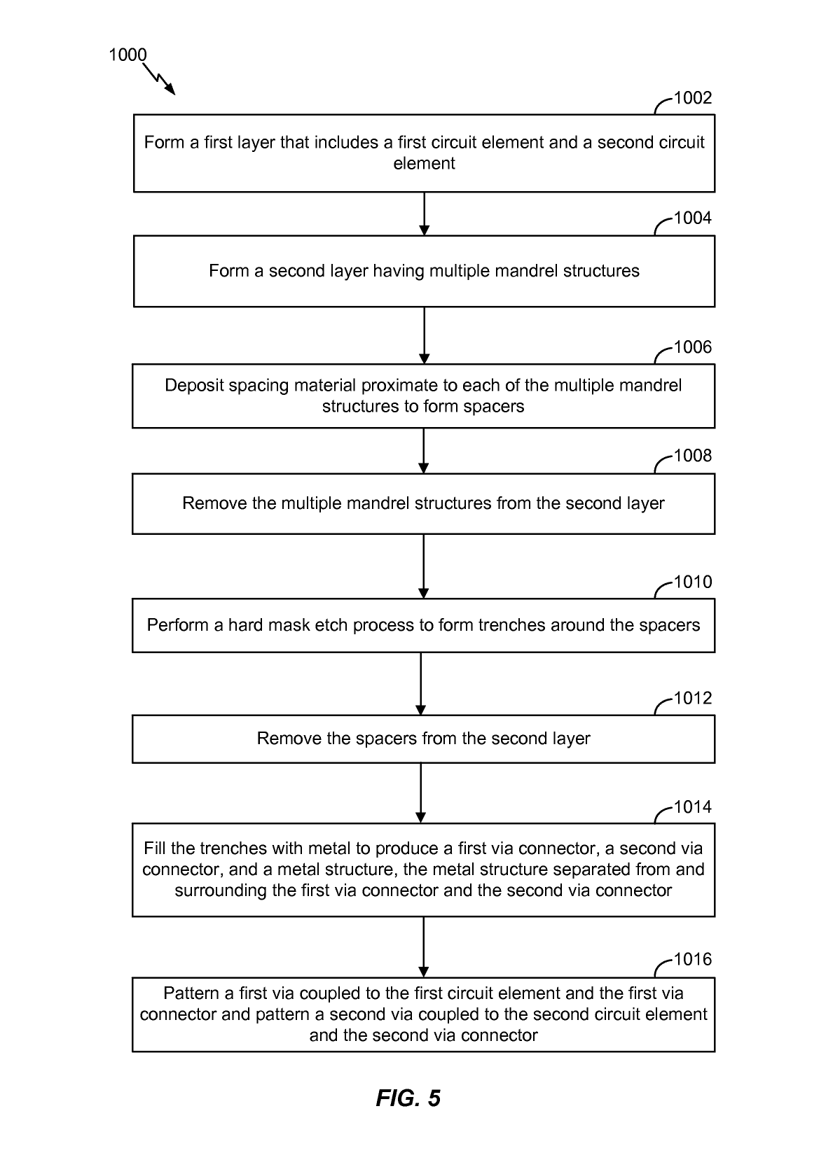

Referring to FIG. 5, a flow diagram of an illustrative aspect of a method 1000 of forming an integrated circuit device is depicted. For example, the integrated circuit device may include the integrated circuit device 100 of FIG. 1. Referring to FIG. 5, a method 1000 of fabricating an integrated circuit device includes forming a first layer that includes a first circuit element and a second circuit element, at 1002, and forming multiple mandrel structures, at 1004. For example, a first layer (e.g., the circuit element layer 140 of FIG. 1) may be formed by an initial stage of an integrated circuit fabrication process. Multiple mandrel structures may be formed as shown in FIG. 3A or FIG. 4A. The method further includes depositing spacing material proximate to each of the multiple mandrel structures to form spacers, at 1006. For example, material may be deposited to form the spacers shown in FIG. 3B or FIG. 4B.

In a particular implementation, the multiple mandrel structures may include a mandrel structure having a ladder shape. For example, the multiple mandrel structures may include the mandrel structure 702 of FIG. 4A, which has a ladder shape. In another particular implementation, the multiple mandrel structures may include a first group of non-contiguous mandrel elements aligned in a first alignment direction and a second group of non-contiguous mandrel elements aligned in the first alignment direction. For example, the multiple mandrel structures may include a first group of non-contiguous mandrel elements (e.g., the mandrel elements 302 and 304) and a second group of non-contiguous elements (e.g., the mandrel elements 306 and 308) of FIG. 3A. Both groups of non-contiguous elements may be aligned in a first alignment direction (e.g., horizontal). Additionally or alternatively, the multiple mandrel structures may include a third unitary mandrel proximate to the first group of non-contiguous mandrel elements. For example, the multiple mandrel structures may include the unitary mandrel 310 that is proximate to the mandrel elements 302 and 304.

The method further includes removing the multiple mandrel structures, at 1008. For example, the mandrel structures shown in FIG. 3A and FIG. 4A may be removed by performing an etching process, or another removal process. The mandrel structures may be removed without performing a cut process using a cut metal pattern, as described with reference to FIG. 3C and FIG. 4C. The method 1000 further includes performing a hard mask etch process to form trenches around the spacers, at 1010, and removing the spacers, at 1012. For example, the trenches 502, 504, and 510 may be formed as illustrated in FIG. 3D. In a particular implementation, the spacers may be used as a hard mask during the hard mask etch process, as described with reference to FIG. 3D.

The method 1000 further includes filling the trenches with metal to produce a first via connector, a second via connector, and a metal structure, at 1014. Examples of the first via connector 102, the second via connector 104, and the metal structure 106 are shown in FIG. 1 and FIG. 2. The metal structure is separated from and encircles (e.g., surrounds) the first via connector and the second via connector. For example, the metal structure 106 has a ladder shape and is separated from and encircles multiple via connectors (e.g. via connectors 102, 104). Forming the first via connector, the second via connector, and the metal structure may form at least part of a second layer (e.g., the first metal layer 142 of FIG. 1). The method 1000 further includes patterning a first via coupled to the first circuit element and the first via connector and patterning a second via coupled to the second circuit element and the second via connector, at 1016. For example, the first via 110 may be coupled to the first gate 134 of the first transistor 130 and coupled to the first via connector 102. The third via 112 may be coupled to the second gate 136 of the second transistor 132 and coupled to the second via connector 104, as shown in FIG. 1.

The method 1000 may form multiple via connectors and a metal structure that is separate from and encircles the multiple via connectors. By forming such a metal structure, multiple via connectors may be formed without performing a cut process using a cut metal pattern, thereby reducing complexity and/or cost of a fabrication process.

The method 1000 of FIG. 5 may be implemented by a field-programmable gate array (FPGA) device, an application-specific integrated circuit (ASIC), a processing unit such as a central processing unit (CPU), a digital signal processor (DSP), a controller, another hardware device, a firmware device, or any combination thereof As an example, the method 1000 of FIG. 5 may be performed by one or more processors that execute instructions stored at a memory, such as a non-transitory computer-readable medium. The one or more processors and the memory may be integrated within equipment of a semiconductor fabrication plant to perform a fabrication process, as described further with reference to FIG. 7.

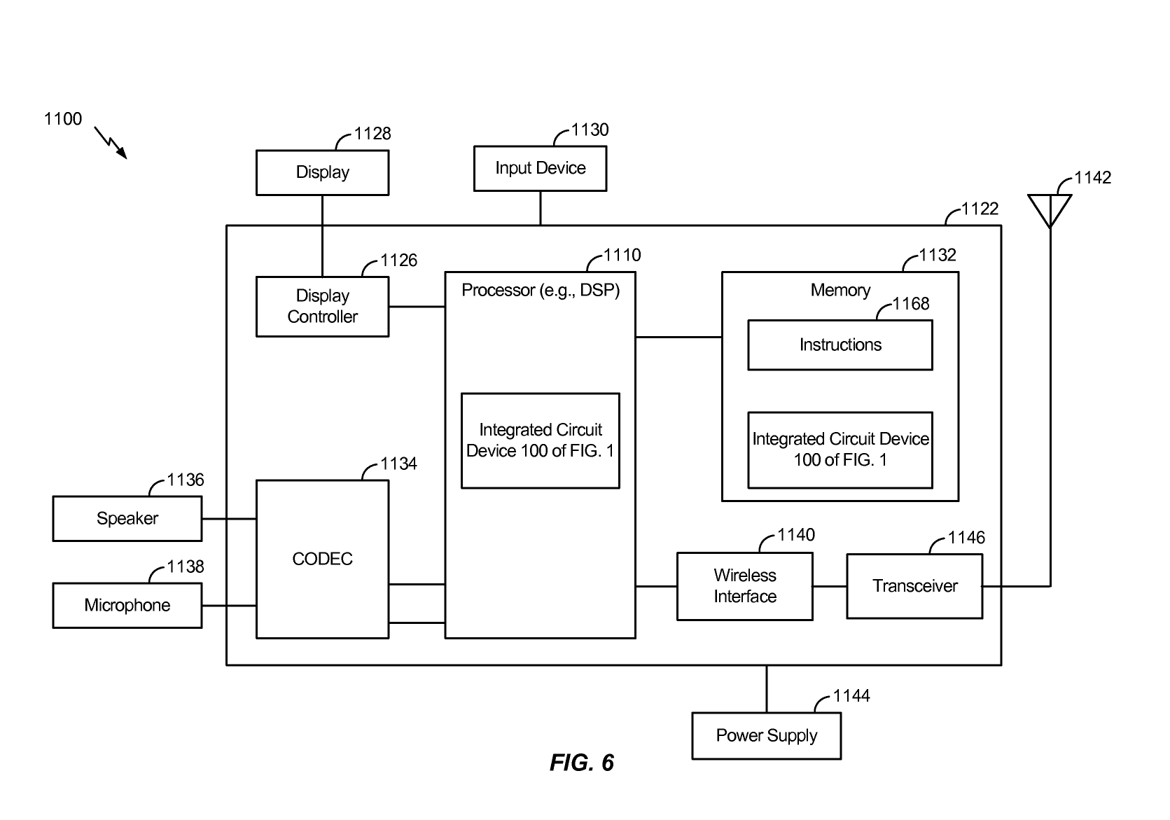

Referring to FIG. 6, a block diagram of a particular illustrative implementation of a wireless communication device 1100 is depicted. The device 1100 may include the integrated circuit device 100 of FIG. 1.

The device 1100 includes a processor 1110, such as a digital signal processor (DSP), coupled to a memory 1132. The processor 1110 may include the integrated circuit device 100 of FIG. 1. For example, the processor 1110 may include a cache, a register, or another memory that includes the integrated circuit device 100 of FIG. 1. As another example, the memory 1132 may include a memory cell that includes the integrated circuit device 100 of FIG. 1.

The memory 1132 includes instructions 1168 (e.g., executable instructions) such as computer-readable instructions or processor-readable instructions. The instructions 1168 may include one or more instructions that are executable by a computer, such as the processor 1110.

FIG. 6 also illustrates a display controller 1126 that is coupled to the processor 1110 and to a display 1128. A coder/decoder (CODEC) 1134 may also be coupled to the processor 1110. A speaker 1136 and a microphone 1138 may be coupled to the CODEC 1134.

FIG. 6 also illustrates that a wireless interface 1140 and a transceiver 1146, such as a wireless controller, may be coupled to the processor 1110 and to an antenna 1142, such that wireless data received via the antenna 1142, the transceiver 1146, and the wireless interface 1140 may be provided to the processor 1110. In some implementations, the processor 1110, the display controller 1126, the memory 1132, the CODEC 1134, the wireless interface 1140, and the transceiver 1146 are included in a system-in-package or system-on-chip device 1122. In some implementations, an input device 1130 and a power supply 1144 are coupled to the system-on-chip device 1122. Moreover, in a particular aspect, as illustrated in FIG. 11, the display 1128, the input device 1130, the speaker 1136, the microphone 1138, the antenna 1142, and the power supply 1144 are external to the system-on-chip device 1122. However, each of the display 1128, the input device 1130, the speaker 1136, the microphone 1138, the antenna 1142, and the power supply 1144 may be coupled to a component of the system-on-chip device 1122, such as an interface or a controller. Although the integrated circuit device 100 is depicted as being included in the processor 1110 or in the memory 1132, respectively, the integrated circuit device 100 may be included in another component of the device 1100 or a component coupled to the device 1100. For example, the integrated circuit device 100 may be included in the wireless interface 1140, the transceiver 1146, the power supply 1144, the input device 1130, the display controller 1126, or another component that includes a memory cell.

In conjunction with one or more of the described aspects of FIGS. 1-6, an apparatus is disclosed that may include means for coupling a first group of vias and means for coupling a second group of vias. The means for coupling the first group of vias may include or correspond to the first via connector 102, one or more other structures or circuits configured to couple a first group of vias, or any combination thereof, and the means for coupling the second group of vias may include or correspond to the second via connector 104, one or more other structures or circuits configured to couple a second group of vias, or any combination thereof

The apparatus may further include means for conducting. The means for conducting may be separated from and may encircle the means for coupling the first group of vias and the means for coupling the second group of vias. The means for conducting may include or correspond to the metal structure 106, one or more other structures or circuits configured to couple a first group of vias, or any combination thereof.

One or more of the disclosed embodiments may be implemented in a system or an apparatus, such as the device 1100, that may include a communications device, a fixed location data unit, a mobile location data unit, a mobile phone, a cellular phone, a satellite phone, a computer, a tablet, a portable computer, or a desktop computer. Additionally, the device 1100 may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that stores or retrieves data or computer instructions, or a combination thereof. As another illustrative, non-limiting example, the system or the apparatus may include remote units, such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof.

The foregoing disclosed devices and functionalities may be designed and configured into computer files (e.g. RTL, GDSII, GERBER, etc.) stored on computer readable media. Some or all such files may be provided to fabrication handlers to fabricate devices based on such files. Resulting products include semiconductor wafers that are then cut into semiconductor dies and packaged into semiconductor chips. The semiconductor chips are then employed in devices described above. FIG. 7 depicts a particular illustrative implementation of an electronic device manufacturing process 1200.

Physical device information 1202 is received at the manufacturing process 1200, such as at a research computer 1206. The physical device information 1202 may include design information representing at least one physical property of a semiconductor device, such as the integrated circuit device 100 of FIG. 1. For example, the physical device information 1202 may include physical parameters, material characteristics, and structure information that is entered via a user interface 1204 coupled to the research computer 1206. The research computer 1206 includes a processor 1208, such as one or more processing cores, coupled to a computer readable medium (e.g., a non-transitory computer readable medium) such as a memory 1210. The memory 1210 may store computer readable instructions that are executable to cause the processor 1208 to transform the physical device information 1202 to comply with a file format and to generate a library file 1212.

In a particular implementation, the library file 1212 includes at least one data file including the transformed design information. For example, the library file 1212 may include a library of semiconductor devices including the integrated circuit device 100 of FIG. 1 that is provided for use with an electronic design automation (EDA) tool 1220.

The library file 1212 may be used in conjunction with the EDA tool 1220 at a design computer 1214 including a processor 1216, such as one or more processing cores, coupled to a memory 1218. The EDA tool 1220 may be stored as processor executable instructions at the memory 1218 to enable a user of the design computer 1214 to design a circuit including the integrated circuit device 100 of FIG. 1 of the library file 1212. For example, a user of the design computer 1214 may enter circuit design information 1222 via a user interface 1224 coupled to the design computer 1214. The circuit design information 1222 may include design information representing at least one physical property of a semiconductor device, such as the integrated circuit device 100 of FIG. 1. To illustrate, the circuit design property may include identification of particular circuits and relationships to other elements in a circuit design, positioning information, feature size information, interconnection information, or other information representing a physical property of a semiconductor device.

The design computer 1214 may be configured to transform the design information, including the circuit design information 1222, to comply with a file format. To illustrate, the file formation may include a database binary file format representing planar geometric shapes, text labels, and other information about a circuit layout in a hierarchical format, such as a Graphic Data System (GDSII) file format. The design computer 1214 may be configured to generate a data file including the transformed design information, such as a GDSII file 1226 that includes information describing the integrated circuit device 100 of FIG. 1, in addition to other circuits or information. To illustrate, the data file may include information corresponding to a system-on-chip (SOC) that includes the integrated circuit device 100 of FIG. 1 and that also includes additional electronic circuits and components within the SOC.

The GDSII file 1226 may be received at a fabrication process 1228 to manufacture the integrated circuit device 100 of FIG. 1, according to transformed information in the GDSII file 1226. For example, a device manufacture process may include providing the GDSII file 1226 to a mask manufacturer 1230 to create one or more masks, such as masks to be used with photolithography processing, illustrated as a representative mask 1232. The mask 1232 may be used during the fabrication process 1228 to generate one or more wafers 1233, which may be tested and separated into dies, such as a representative die 1236. The die 1236 includes a circuit including the integrated circuit device 100 of FIG. 1.

For example, the fabrication process 1228 may include a processor 1234 and a memory 1235 to initiate and/or control the fabrication process 1228. The memory 1235 may include executable instructions such as computer-readable instructions or processor-readable instructions. The executable instructions may include one or more instructions that are executable by a computer such as the processor 1234.

The fabrication process 1228 may be implemented by a fabrication system that is fully automated or partially automated. For example, the fabrication process 1228 may be automated according to a schedule. The fabrication system may include fabrication equipment (e.g., processing tools) to perform one or more operations to form a semiconductor device. For example, deposit one or more materials, epitaxially grow one or more materials, conformally deposit one or more materials, apply a hardmask, apply an etching mask, perform etching, perform planarization, form a dummy gate stack, form a gate stack, perform a standard clean 1 type, etc.

The fabrication system (e.g., an automated system that performs the fabrication process 1228) may have a distributed architecture (e.g., a hierarchy). For example, the fabrication system may include one or more processors, such as the processor 1234, one or more memories, such as the memory 1235, and/or controllers that are distributed according to the distributed architecture. The distributed architecture may include a high-level processor that controls or initiates operations of one or more low-level systems. For example, a high-level portion of the fabrication process 1228 may include one or more processors, such as the processor 1234, and the low-level systems may each include or may be controlled by one or more corresponding controllers. A particular controller of a particular low-level system may receive one or more instructions (e.g., commands) from a high-level system, may issue sub-commands to subordinate modules or process tools, and may communicate status data back to the high-level system. Each of the one or more low-level systems may be associated with one or more corresponding pieces of fabrication equipment (e.g., processing tools). In a particular aspect, the fabrication system may include multiple processors that are distributed in the fabrication system. For example, a controller of a low-level system component of the fabrication system may include a processor, such as the processor 1234.

Alternatively, the processor 1234 may be a part of a high-level system, subsystem, or component of the fabrication system. In another aspect, the processor 1234 includes distributed processing at various levels and components of a fabrication system.

Thus, the processor 1234 may include processor-executable instructions that, when executed by the processor 1234, cause the processor 1234 to initiate or control formation of an integrated circuit device. In a particular aspect, the processor 1234 may perform operations including initiating formation of a first layer that includes a first circuit element and a second circuit element. The operations may include initiating formation of multiple mandrel structures. The operations may include initiating deposition of spacing material proximate to each of the multiple mandrel structures to form spacers. The operations may include initiating removal of the multiple mandrel structures. The operations may include initiating performance of a hard mask etch process to form trenches around the spacers. The operations may include initiating removal of the spacers. The operations may include initiating filling of the trenches with metal to produce a first via connector, a second via connector, and a metal structure, the metal structure separated from and encircling the first via connector and the second via connector. The operations may further include initiating patterning of a first via coupled to the first circuit element and the first via connector and patterning of a second via coupled to the second circuit element and the second via connector. One or more of the operations may be performed by controlling one of more deposition tools, such as a molecular beam epitaxial growth tool, a flowable chemical vapor deposition (FCVD) tool, a conformal deposition tool, or a spin-on deposition tool, one or more removal tools, such as a chemical removal tool, a reactive gas removal tool, a hydrogen reaction removal tool, or a standard clean 1 type removal tool, one or more etchers, such as a wet etcher, a dry etcher, or a plasma etcher, one or more dissolving tools, such as a developer or developing tool, one or more other tools, or a combination thereof.

The executable instructions included in the memory 1235 may enable the processor 1234 to initiate formation of a semiconductor device such as the integrated circuit device 100 of FIG. 1. In a particular implementation, the memory 1235 is a non-transitory computer readable medium storing processor-executable instructions that are executable by the processor 1234 to cause the processor 1234 to perform the above-described operations.

The die 1236 may be provided to a packaging process 1238 where the die 1236 is incorporated into a representative package 1240. For example, the package 1240 may include the single die 1236 or multiple dies, such as a system-in-package (SiP) arrangement. The package 1240 may be configured to conform to one or more standards or specifications, such as Joint Electron Device Engineering Council (JEDEC) standards.

Information regarding the package 1240 may be distributed to various product designers, such as via a component library stored at a computer 1246. The computer 1246 may include a processor 1248, such as one or more processing cores, coupled to a memory 1250. A printed circuit board (PCB) tool may be stored as processor executable instructions at the memory 1250 to process PCB design information 1242 received from a user of the computer 1246 via a user interface 1244. The PCB design information 1242 may include physical positioning information of a packaged semiconductor device on a circuit board, the packaged semiconductor device corresponding to the package 1240 including the integrated circuit device 100 of FIG. 1.

The computer 1246 may be configured to transform the PCB design information 1242 to generate a data file, such as a GERBER file 1252 with data that includes physical positioning information of a packaged semiconductor device on a circuit board, as well as layout of electrical connections such as traces and vias, where the packaged semiconductor device corresponds to the package 1240 including the integrated circuit device 100 of FIG. 1. In other implementations, the data file generated by the transformed PCB design information may have a format other than a GERBER format.

The GERBER file 1252 may be received at a board assembly process 1254 and used to create PCBs, such as a representative PCB 1256, manufactured in accordance with the design information stored within the GERBER file 1252. For example, the GERBER file 1252 may be uploaded to one or more machines to perform various steps of a PCB production process. The PCB 1256 may be populated with electronic components including the package 1240 to form a representative printed circuit assembly (PCA) 1258.

The PCA 1258 may be received at a product manufacture process 1260 and integrated into one or more electronic devices, such as a first representative electronic device 1262 and a second representative electronic device 1264. For example, the first representative electronic device 1262, the second representative electronic device 1264, or both, may include or correspond to the wireless communication device 1100 of FIG. 6. As an illustrative, non-limiting example, the first representative electronic device 1262, the second representative electronic device 1264, or both, may include or correspond to a communications device, a fixed location data unit, a mobile location data unit, a mobile phone, a cellular phone, a satellite phone, a computer, a tablet, a portable computer, or a desktop computer. Alternatively or additionally, the first representative electronic device 1262, the second representative electronic device 1264, or both, may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that stores or retrieves data or computer instructions, or a combination thereof, into which the integrated circuit device 100 of FIG. 1 is integrated. As another illustrative, non-limiting example, one or more of the electronic devices 1262 and 1264 may include remote units, such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 7 illustrates remote units according to teachings of the disclosure, the disclosure is not limited to these illustrated units. Aspects of the disclosure may be suitably employed in any device which includes active integrated circuitry including memory and on-chip circuitry.

A device that includes the integrated circuit device 100 of FIG. 1 may be fabricated, processed, and incorporated into an electronic device, as described in the illustrative process 1200. One or more aspects disclosed with respect to FIGS. 1-6 may be included at various processing stages, such as within the library file 1212, the GDSII file 1226, and the GERBER file 1252, as well as stored at the memory 1210 of the research computer 1206, the memory 1218 of the design computer 1214, the memory 1250 of the computer 1246, the memory of one or more other computers or processors (not shown) used at the various stages, such as at the board assembly process 1254, and also incorporated into one or more other physical implementations such as the mask 1232, the die 1236, the package 1240, the PCA 1258, other products such as prototype circuits or devices (not shown), or any combination thereof. Although various representative stages are depicted with reference to FIGS. 1-7, in other implementations fewer stages may be used or additional stages may be included. Similarly, the process 1200 of FIG. 7 may be performed by a single entity or by one or more entities performing various stages of the process 1200.

Although one or more of FIGS. 1-7 may illustrate systems, apparatuses, and/or methods according to the teachings of the disclosure, the disclosure is not limited to these illustrated systems, apparatuses, and/or methods. One or more functions or components of any of FIGS. 1-7 as illustrated or described herein may be combined with one or more other portions of another of FIGS. 1-7. Accordingly, no single implementation described herein should be construed as limiting and aspects of the disclosure may be suitably combined without departing form the teachings of the disclosure.

Those of skill would further appreciate that the various illustrative logical blocks, configurations, modules, circuits, and algorithm steps described in connection with the implementations disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the disclosure may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal In the alternative, the processor and the storage medium may reside as discrete components in a computing device or user terminal

The previous description is provided to enable a person skilled in the art to make or use the disclosed implementations. Various modifications to these implementations will be readily apparent to those skilled in the art, and the principles defined herein may be applied to other implementations without departing from the scope of the disclosure. Thus, the present disclosure is not intended to be limited to the implementations shown herein but is to be accorded the widest scope possible consistent with the principles and novel features as defined by the following claims.

What is claimed is:

1. An apparatus comprising:
a first via of an integrated circuit;
a second via of the integrated circuit;
a first via connector coupled to the first via;
a second via connector coupled to the second via; and
a metal structure separated from and encircling the first via connector and the second via connector.

2. The apparatus of claim 1, wherein the integrated circuit comprises a memory.

3. The apparatus of claim 2, wherein the memory comprises a static random access memory (SRAM) device.

4. The apparatus of claim 1, wherein the first via connector, the second via connector, and the metal structure are included in a first metal layer of the integrated circuit, and wherein the first metal layer is disposed above a layer containing at least one circuit element.

5. The apparatus of claim 1, wherein the first via connector comprises a word line connection pad coupled to a word line of a memory cell.

6. The apparatus of claim 1, wherein the second via connector comprises a word line connection pad coupled to a word line of a memory cell.

7. The apparatus of claim 1, wherein the metal structure has a ladder shape.

8. The apparatus of claim 7, wherein the metal structure is coupled to a voltage source or to ground.

9. The apparatus of claim 1, wherein the metal structure comprises a voltage source connection.

10. The apparatus of claim 1, wherein the first via couples a gate of a transistor to the first via connector, and wherein a third via couples the first via connector to a word line.

11. The apparatus of claim 10, wherein the gate is included in a first layer of the integrated circuit, wherein the first via connector, the second via connector, and the metal structure are included in a first metal layer of the integrated circuit, and wherein the word line is included in a second metal layer of the integrated circuit.

12. The apparatus of claim 10, wherein the integrated circuit comprises a static random access memory (SRAM) device, and wherein the transistor and the word line are included in a six transistor (6T) memory cell of the SRAM device.

13. A method of fabricating an integrated circuit device comprising:
forming a first layer that includes a circuit element; and
forming a second layer that includes a first via connector, a second via connector, and a metal structure, the metal structure separated from and encircling the first via connector and the second via connector.

14. The method of claim 13, further comprising:
forming multiple mandrel structures after forming the first layer; and
depositing spacing material proximate to each of the multiple mandrel structures to form spacers.

15. The method of claim 14, wherein the multiple mandrel structures include a mandrel structure having a ladder shape.

16. The method of claim 14, wherein the multiple mandrel structures include a first group of non-contiguous mandrel elements aligned in a first alignment direction and a second group of non-contiguous mandrel elements aligned in the first alignment direction.

17. The method of claim 16, wherein the first alignment direction is horizontal.

18. The method of claim 16, wherein the multiple mandrel structures include a third unitary mandrel proximate to the first group of non-contiguous mandrel elements.

19. The method of claim 14, further comprising:
removing the multiple mandrel structures;
performing a hard mask etch process to form trenches around the spacers; and
removing the spacers.

20. The method of claim 19, wherein the multiple mandrel structures are removed without performing a cut process using a cut metal pattern.

21. The method of claim 19, wherein the spacers are used as a hard mask during the hard mask etch process.

22. The method of claim 19, further comprising filling the trenches with metal to form the first via connector, the second via connector, and the metal structure.

23. The method of claim 22, further comprising patterning a first via coupled to the circuit element and the first via connector and patterning a second via coupled to a second circuit element of the first layer and the second via connector.

24. An apparatus comprising:
means for coupling a first group of vias;
means for coupling a second group of vias; and
means for conducting, the means for conducting separated from and encircling the means for coupling the first group of vias and the means for coupling the second group of vias.

25. The apparatus of claim 24, wherein the means for conducting has a ladder shape.

26. The apparatus of claim 24, wherein the means for conducting comprises a voltage source connection coupled to a voltage source.

27. The apparatus of claim 24, wherein a first via of the first group of vias couples a gate of a transistor to the means for coupling the first group of vias, and wherein a second via couples the means for coupling the first group of vias to a word line.

28. A non-transitory computer-readable medium storing instructions that, when executed by a processor, cause the processor to perform operations comprising:
initiating formation of a first layer that includes a first circuit element and a second circuit element;
initiating formation of multiple mandrel structures;
initiating deposition of spacing material proximate to each of the multiple mandrel structures to form spacers;
initiating removal of the multiple mandrel structures;
initiating performance of a hard mask etch process to form trenches around the spacers;
initiating removal of the spacers;
initiating filling of the trenches with metal to produce a first via connector, a second via connector, and a metal structure, the metal structure separated from and encircling the first via connector and the second via connector; and
initiating patterning of a first via coupled to the first circuit element and the first via connector and patterning of a second via coupled to the second circuit element and the second via connector.

29. The non-transitory computer-readable medium of claim 28, wherein the metal structure has a ladder shape.

30. The non-transitory computer-readable medium of claim 28, wherein the multiple mandrel structures are removed without performing a cut process using a cut metal pattern.
